(19) United States
(12) Patent Application Publication
(10) Pub. No.: US 2011/0284873 A1
(43) Pub. Date: Nov. 24, 2011

(54) SILICON CARBIDE SUBSTRATE

(75) Inventors: Taro Nishiguchi, Hyogo (JP); Makoto Sasaki, Hyogo (JP); Shin Harada, Osaka (JP); Kyoko Okita, Hyogo (JP); Hiroki Inoue, Hyogo (JP); Shinsuke Fujiwara, Hyogo (JP); Yasuo Namikawa, Hyogo (JP)

(73) Assignee: SUMITOMO ELECTRIC INDUSTRIES, LTD., Osaka-shi (JP)

(21) Appl. No.: 13/146,432

(22) PCT Filed: Sep. 28, 2010
(86) PCT No.: PCT/JP2010/066809

§ 371 Date: Jul. 27, 2011

(30) Foreign Application Priority Data
Dec. 16, 2009 (JP) 2009-285239

(51) Int. Cl. H01L 29/161

(52) U.S. Cl. 257/77; 257/E29.084

(57) ABSTRACT

A silicon carbide substrate has a substrate region and a support portion. The substrate region has a first single crystal substrate. The support portion is joined to a first backside surface of the first single crystal. The dislocation density of the first single crystal substrate is lower than the dislocation density of the support portion. At least one of the substrate region and the support portion has voids.

### TECHNICAL FIELD

The present invention relates to a silicon carbide substrate.

### BACKGROUND ART

Recently, a SiC (silicon carbide) substrate has been introduced as a semiconductor substrate used for manufacturing semiconductor devices. As compared with more widely used Si (silicon), SiC has wider bandgap. Therefore, a semiconductor device using a SiC substrate has advantages such as high breakdown voltage and low on-resistance and, in addition, its property does not much degrade in high-temperature environment.

In order to enable efficient manufacturing of semiconductor devices, the substrate must be of a certain size or larger. According to U.S. Pat. No. 7,314,520 (Patent Document 1), it is possible to manufacture a SiC substrate having the size of at least 76 mm (3 inches).

### PRIOR ART DOCUMENTS

### Patent Documents

Patent Document 1: U.S. Pat. No. 7,314,520

### SUMMARY OF THE INVENTION

### Problems to be Solved by the Invention

Industrially available size of SiC single crystal substrate is about 100 mm (4 inches) at the largest and, therefore, it has been difficult to efficiently manufacture semiconductor devices by using a large single-crystal substrate. When characteristics of a plane other than the (0001) plane are to be utilized in hexagonal system SiC, this poses a particularly serious problem. This will be discussed in the following.

A SiC single crystal substrate with a very small number of defects is typically manufactured by cutting a SiC ingot obtained through surface growth of the (0001) plane that is less susceptible to stacking fault. Therefore, it follows that a single crystal substrate having plane orientation other than the (0001) plane is cut not parallel to the surface of growth. As a result, it becomes difficult to ensure the full size of single crystal substrate, or to effectively make use of large part of the ingot. Consequently, it is particularly difficult to manufacture with high efficiency semiconductor devices utilizing a plane other than the (0001) plane of SiC.

As an alternative to the effort of enlarging the size of SiC single crystal substrate involving difficulties, use of a silicon carbide substrate having a support portion and a plurality of small single crystal substrates joined thereon has been considered. The silicon carbide substrate can be made larger as needed by increasing the number of single crystal substrates.

However, the silicon carbide substrate having the support portion and single crystal substrates joined to each other as described above is susceptible to warpage and, possibly, cracks, because of differences in property between the single crystal substrate and the support portion.

The present invention was made in view of the foregoing, and its object is to provide a silicon carbide substrate having a support portion and a single crystal substrate joined to each other, which is less prone to warpage.

### Means for Solving the Problems

The silicon carbide substrate in accordance with the present invention has a substrate region and a support portion. The substrate region has a first single crystal substrate. The first single crystal substrate has a first front-side surface and a first backside surface opposite to each other and a first side surface connecting the first front-side surface and the first backside surface. The support portion is joined to the first backside surface. The dislocation density of the first single crystal substrate is lower than the dislocation density of the support portion. At least one of the substrate region and the support portion has voids.

According to the present invention, since the dislocation density of the first single crystal substrate is lower than the dislocation density of the support portion, extremely high crystal quality of silicon carbide substrate can be attained in the first single crystal substrate. Further, since stress in the silicon carbide substrate is alleviated by voids, warpage of the silicon carbide substrate can be reduced.

Preferably, the number of voids per unit volume in the support portion is larger than in the first single crystal substrate. The number of voids in the first single crystal substrate is made small while the number of voids in the support portion is made larger, so that sufficiently large number of voids to alleviate stress can be provided. Thus, warpage of the silicon carbide substrate can be reduced without lowering the quality of first single crystal substrate.

Preferably, the first single crystal substrate has a first concentration as impurity concentration per unit volume, the support portion has a second concentration as impurity concentration per unit volume, and the second concentration is higher than the first concentration. Therefore, electric resistance of the support portion can be made lower.

Preferably, the substrate region includes a second single crystal substrate. The second single crystal substrate has a second front-side surface and a second backside surface opposite to each other and a second side surface connecting the second front-side surface and the second backside surface. The second backside surface is joined to the support portion. Since both the first and second front-side surfaces are provided as the surfaces of substrate region, the surface area of silicon carbide substrate can be increased.

Preferably, the substrate region includes a space portion positioned between the first and second side surfaces facing each other. The space portion has a filled portion partially filling the space portion. Therefore, deposition of foreign matter in the space portion can be reduced than when the filled portion is not provided.

Preferably, the first single crystal substrate has a first porosity, and the space portion has a second porosity. The second porosity is higher than the first porosity. Deformation of the space portion promotes stress alleviation. Thus, warpage of the silicon carbide substrate can further be reduced.

Preferably, the substrate region includes a third single crystal substrate. The third single crystal substrate is joined to the first front-side surface of the first single crystal substrate. Thus, the substrate region comes to have a stacked structure.

Preferably, the number of voids per unit volume in the support potion is at least 10 cm⁻³. Thus, warpage of the silicon carbide substrate can further be reduced.

Preferably, the number of voids relates to voids whose volume is at least 1 μm³. Thus, warpage of the silicon carbide substrate can more reliably be reduced.

Preferably, the first front-side surface has an off angle of at least 50° and at most 65° with respect to the {0001} plane. More preferably, an angle formed by off orientation of the first front-side surface and <1-100> direction of the first single crystal substrate is at most 5°. Further preferably, off angle of the first front-side surface with respect to the {03-38} plane in <1-100> direction of the first single crystal substrate is at least −3° and at most 5°. Thus, channel mobility of the first front-side surface can be improved than when the first front-side surface is the {0001} plane.

Preferably, the first front-side surface has an off angle of at least 50° and at most 65° with respect to the {0001} plane. An angle formed by off orientation of the first front-side surface and <11-20> direction of the first single crystal substrate is at most 5°. Thus, channel mobility of the first front-side surface can be improved than when the first front-side surface is the {0001} plane.

Preferably, the first backside surface of the first single crystal substrate is formed by slicing. Specifically, the first backside surface is formed by slicing and not subjected to polishing thereafter. Thus, the first backside surface has ups and downs. The space in the concave portions of the ups and downs can be used as gaps in which sublimation gas accumulates, when the support portion is provided on the first backside surface by sublimation.

### Effects of the Invention

As is apparent from the description above, the present invention provides a silicon carbide substrate having a support portion and a single crystal substrate joined to each other, which is less prone to warpage.

### BRIEF DESCRIPTION OF THE DRAWINGS

FIG. 1 is a plan view schematically showing a structure of a silicon carbide substrate in accordance with Embodiment 1 of the present invention.

FIG. 2 is a schematic cross-sectional view taken along the line II-II of FIG. 1.

FIG. 3 is a cross sectional view schematically showing a first step of the method of manufacturing a silicon carbide substrate in accordance with Embodiment 1 of the present invention.

FIG. 4 is a partial enlargement of FIG. 3.

FIG. 5 is a partial cross-sectional view schematically showing directions of material movement caused by sublimation, at the second step of the method of manufacturing a silicon carbide substrate in accordance with Embodiment 1 of the present invention.

FIG. 6 is a partial cross-sectional view schematically showing directions of gap movement caused by sublimation, at the second step of the method of manufacturing a silicon carbide substrate in accordance with Embodiment 1 of the present invention.

FIG. 7 is a partial cross-sectional view schematically showing directions of void movement caused by sublimation, at the second step of the method of manufacturing a silicon carbide substrate in accordance with Embodiment 1 of the present invention.

FIG. 8 is a cross-sectional view schematically showing a structure of the silicon carbide substrate in accordance with Embodiment 2 of the present invention.

FIG. 9 is a cross-sectional view schematically showing a structure of the silicon carbide substrate in accordance with Embodiment 3 of the present invention.

FIG. 10 is a cross-sectional view schematically showing a structure of the silicon carbide substrate in accordance with Embodiment 4 of the present invention.

FIG. 11 is a cross-sectional view schematically showing a step of the method of manufacturing a silicon carbide substrate in accordance with a modification of Embodiment 4 of the present invention.

FIG. 12 is a cross-sectional view schematically showing a structure of the silicon carbide substrate in accordance with Embodiment 5 of the present invention.

FIG. 13 is a cross-sectional view schematically showing a structure of the silicon carbide substrate in accordance with Embodiment 6 of the present invention.

FIG. 14 is a partial cross-sectional view schematically showing a structure of the semiconductor device in accordance with Embodiment 7 of the present invention.

FIG. 15 is a schematic flowchart representing the method of manufacturing a semiconductor device in accordance with Embodiment 7 of the present invention.

FIG. 16 is a partial cross-sectional view schematically showing the first step of the method of manufacturing a semiconductor device in accordance with Embodiment 7 of the present invention.

FIG. 17 is a partial cross-sectional view schematically showing the second step of the method of manufacturing a semiconductor device in accordance with Embodiment 7 of the present invention.

FIG. 18 is a partial cross-sectional view schematically showing the third step of the method of manufacturing a semiconductor device in accordance with Embodiment 7 of the present invention.

FIG. 19 is a partial cross-sectional view schematically showing the fourth step of the method of manufacturing a semiconductor device in accordance with Embodiment 7 of the present invention.

### MODES FOR CARRYING OUT THE INVENTION

In the following, embodiments of the present invention will be described with reference to the figures.

### Embodiment 1

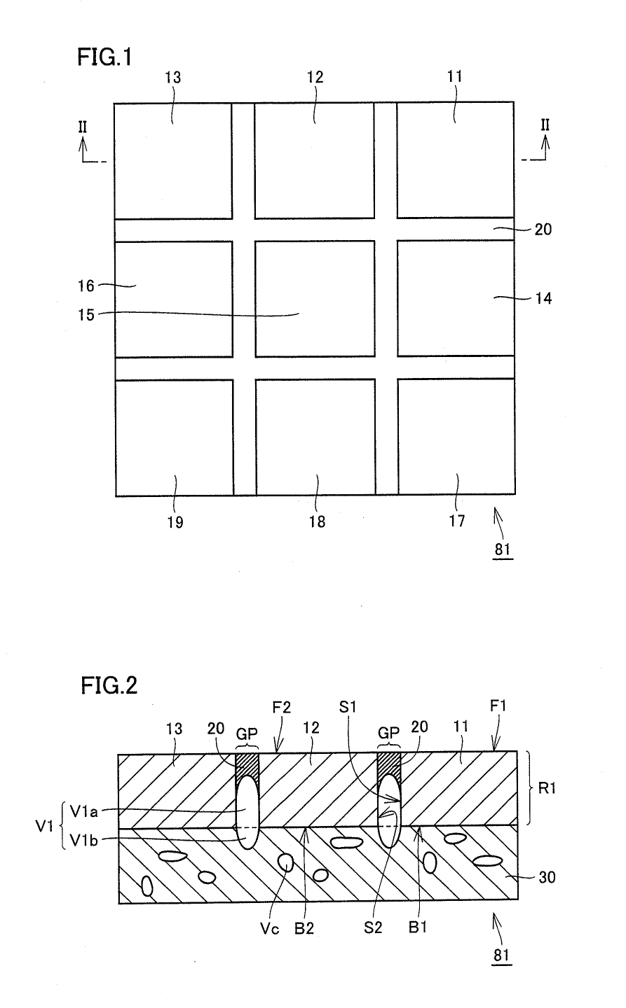

Referring to FIGS. 1 and 2, a silicon carbide substrate 81 in accordance with the present embodiment has a support portion 30 and a substrate region R1. Substrate region R1 has single crystal substrates 11 to 19 and spaces (space portions) GP. Space portion GP has a filled portion 20. Substrate region R1 and support portion 30 have a void V1 bridging the interface therebetween. Specifically, void V1 has a void V1a included in substrate region R1 and a void V1b included in support portion 30. Void V1 is positioned at the border between each of single crystal substrates 11 to 19 when viewed two-dimensionally. Further, support portion 30 has voids Vc therein.

Single crystal substrate 11 (first single crystal substrate) has a first front-side surface F1 and a first backside surface B1 opposite to each other, and a first side surface S1 connecting the first front-side surface F1 and the first backside surface B1. Single crystal substrate 12 (second single crystal substrate) has a second front-side surface F2 and a second backside surface B2 opposite to each other, and a second side surface S2 connecting the second front-side surface F2 and the second backside surface B2. The first and second single crystal substrates are arranged such that the first and second side surfaces S1 and S2 face each other with a space GP therebetween. The shortest distance between the first and second side surfaces is preferably at most 5 mm, more preferably at most 1 mm, further preferably at most 100 and most preferably at most 10 μm.

The front-side surface of each of single crystal substrates 11 to 19 preferably has the plane orientation of {03-38}. It is noted, however, that {0001}, {11-20} or {1-100} may be used as the plane orientation. Further, a plane off from each of the above-mentioned plane orientation by a few degrees may also be used.

Filled portion 20 fills a part of space GP to connect the first and second front-side surfaces F1 and F2. Since space GP has relatively large void V1a as shown in FIG. 2, it has, higher porosity (second porosity) as compared with the porosity (first porosity) of each of single crystal substrates 11 to 19.

Support portion 30 is joined to each of single crystal substrates 11 to 19, for example, to each of the first and second backside surfaces B1 and B2. Support portion 30 has, for example, a disk-shape, of which diameter is preferably at least 50 mm, and more preferably, at least 150 mm.

The number of voids per unit volume is larger in support portion 30 than in each of single crystal substrates 11 to 19. Preferably, the number of voids per unit volume in support portion 30 is at least 10 cm⁻³. Here, the number of voids refers to the number of voids having a certain volume or larger, and the volume is, for example, 1 μm³.

Further, the dislocation density of each of single crystal substrates 11 to 19 is lower than the dislocation density of support portion 30. Specifically, crystal quality is higher in single crystal substrates 11 to 19 than in support portion 30.

Preferably, each of single crystal substrates 11 to 19 has a first concentration as impurity concentration per unit volume, and support portion 30 has a second concentration as the impurity concentration per unit volume. The second concentration is higher than the first concentration.

Next, the method of manufacturing silicon carbide substrate 81 will be described. For simplicity of description, in the following, only the single crystal substrates 11 and 12 may be referred to among single crystal substrates 11 to 19. It is noted, however, that single crystal substrates 13 to 19 are processed in the same manner as single crystal substrates 11 and 12.

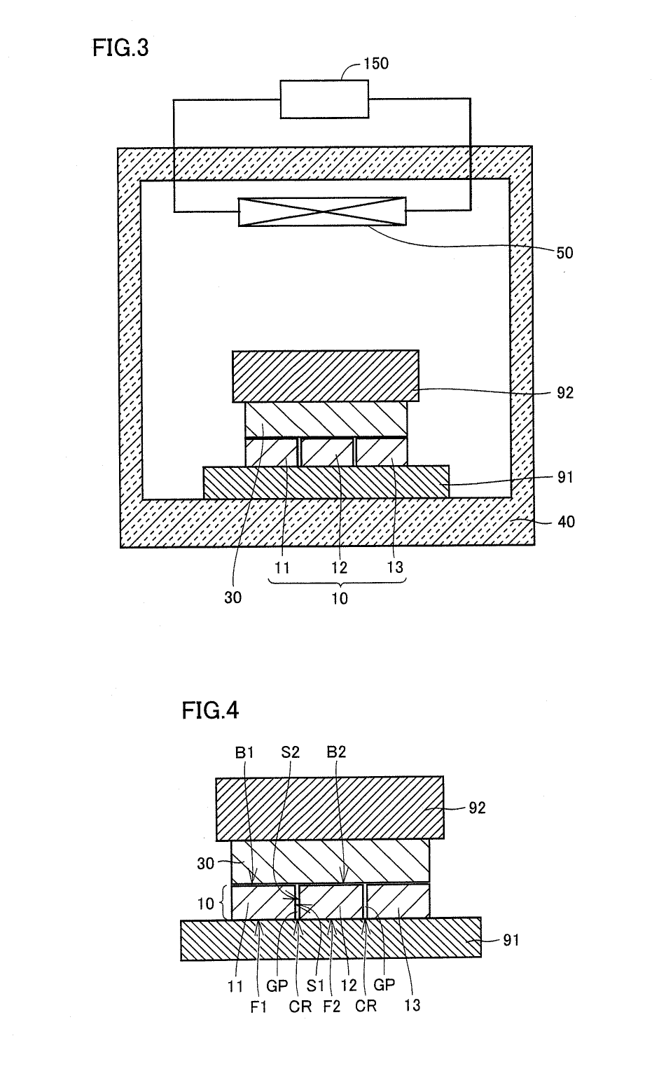

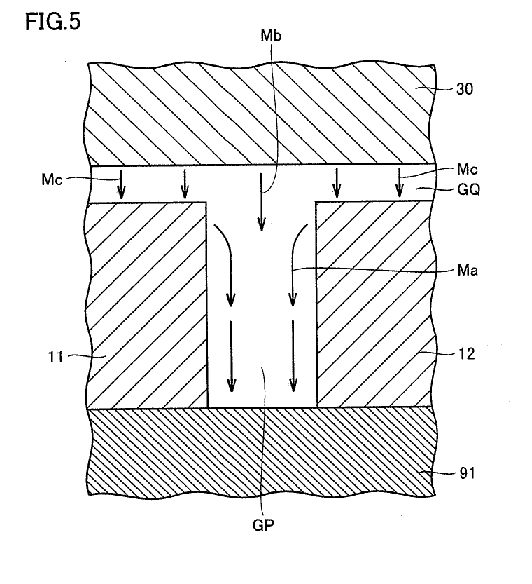

Referring to FIGS. 3 and 4, support portion 30, single crystal substrates 11 to 19, that is, a group 10 of single crystal substrates, and a heating apparatus are prepared. The heating apparatus has first and second heating bodies 91 and 92, a heat-insulating container 40, a heater 50, and a heater power source 150. Heat-insulating container 40 is formed of a material having high heat-insulation property. Heater 50 is, for example, an electric resistance heater. The first and second heating bodies 91 and 92 absorb radiant heat from heater 50 and re-radiate the heat, to attain the function of heating support portion 30 and the group 10 of single crystal substrates. First and second heating bodies 91 and 92 are formed, for example, of graphite having low porosity.

Thereafter, first heating body 91, the group 10 of single crystal substrates, support portion 30 and second heating body 92 are arranged stacked in this order. Specifically, first, single crystal substrates 11 to 19 are arranged in a matrix on first heating body 91. By way of example, single crystal substrates 11 and 12 are arranged such that the first and second side surfaces S1 and S2 face each other with a space GP therebetween. Then, on the surfaces of group 10 of single crystal substrates, support portion 30 is placed. Thereafter, on support portion 30, second heating body 92 is placed. Thereafter, the first heating body, the group 10 of single crystal substrates, support portion 30 and the second heating body 92 stacked one after another are housed in heat-insulating container 40 provided with heater 50.

Next, the atmosphere in heat-insulating container 40 is set to a reduced pressure atmosphere. Pressure of the atmosphere is set to be higher than 10⁻¹ Pa and lower than 10⁴ Pa.

The atmosphere described above may be an inert gas atmosphere. As the inert gas, rare gas such as He or Ar, nitrogen gas, or a mixed gas of rare gas and nitrogen gas may be used. When the mixed gas is used, the ratio of nitrogen gas is, for example, 60%. The pressure in heat-insulating container 40 is preferably at most 50 kPa, and more preferably at most 10 kPa.

Thereafter, by heater 50, the group 10 of single crystal substrates and support portion 30 are heated to a temperature that causes sublimation and re-crystallization reaction, through first and second heating bodies 91 and 92. Heating is done to produce temperature difference such that the temperature of support portion 30 becomes higher than the temperature of group 10 of single crystal substrates.

Referring to FIG. 5, at the start of heating mentioned above, support portion 30 is simply placed on each of single crystal substrates 11 and 12 and not joined thereto. Therefore, between each of the backside surfaces (upper surfaces in FIG. 5) of single crystal substrates 11 and 12 and support portion 30, there are small gaps GQ. Further, between single crystal substrates 11 and 12, a space GP is formed, as described above. Particularly, if the backside surfaces of single crystal substrates 11 and 12 are formed by slicing, that is, formed by slicing and not subjected to polishing, there are ups and downs on the backside surfaces. Accordingly, by the spaces in concave portions of ups and downs, gaps of appropriate size can easily and reliably be provided.

When the temperature of support portion 30 is made higher than that of each of single crystal substrates 11 and 12 as described above, material movement occurs because of sublimation, in gap GQ as indicated by an arrow Mc. Further, material movement occurs because of sublimation from support portion 30 to space GP, as indicated by an arrow Mb. Further, material movement occurs because of sublimation in space GP as indicated by an arrow Ma, from the side of backside surface (upper side in the figure) to the side of front-side surface (lower side in the figure) of each of single crystal substrates 11 and 12.

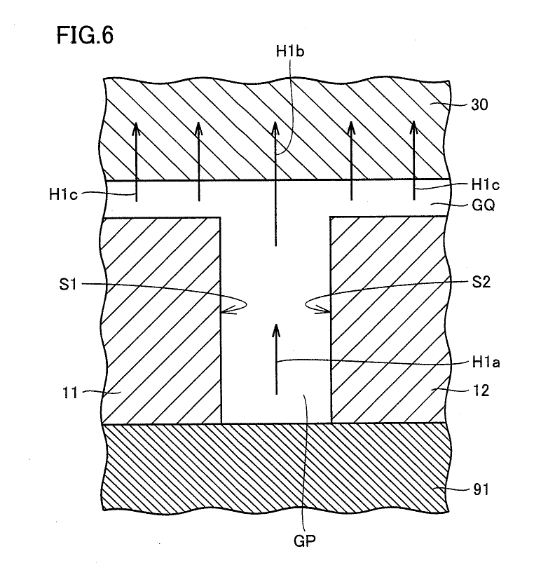

Further, referring to FIG. 6, the material movement indicated by arrows Ma to Mc in FIG. 5 correspond to cavity movement of cavities in space GP and gap GQ, indicated by arrows H1a to H1c in FIG. 6. Here, the height of gap GQ (dimension in the vertical direction in the figure) varies significantly in the plane, and because of the variation, velocity of cavity movement (arrow H1c in the figure) corresponding to gap GP varies significantly in the plane.

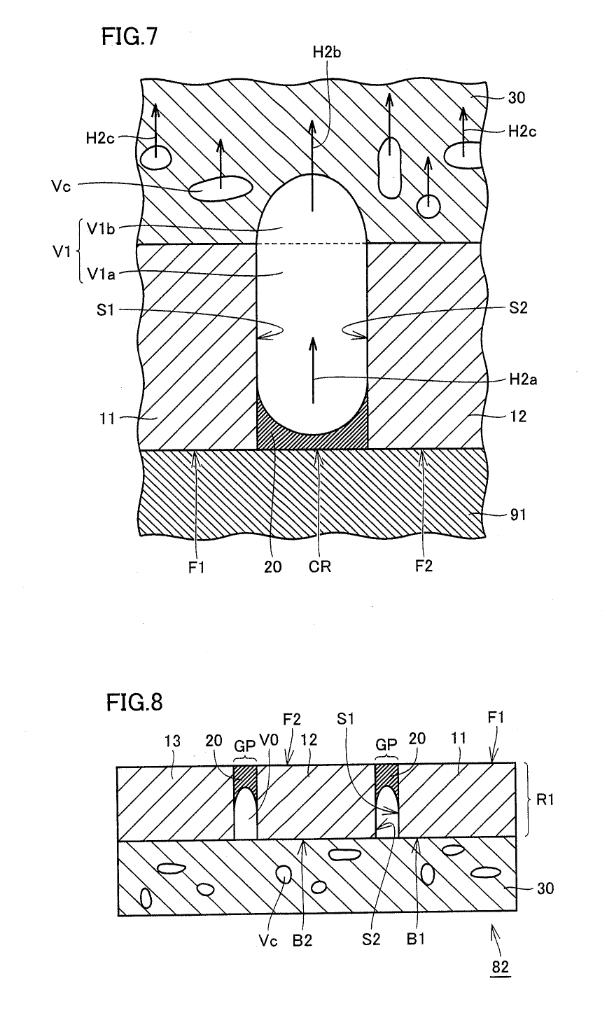

Further, referring to FIG. 7, because of the variation, the cavity corresponding to gap GQ (FIG. 6) cannot move with its shape retained, and instead, a plurality of voids Vc (FIG. 7) are generated.

Further, by the movement of cavity corresponding to space GP indicated by arrows H1a and H1b (FIG. 6), filled portion 20 filling a part of space GP is formed to connect first and second front-side surfaces F1 and F2. As a result, void V1 consisting of void V1b in support portion 30 facing space GP (FIG. 7) and void V1a positioned in space GP (FIG. 7) is generated.

As the heating continues, voids V1a, V1b and Vc move as indicated by arrows H2a, H2b and H2c, respectively. Thus, silicon carbide substrate 81 shown in FIG. 2 is obtained.

According to the present embodiment, since the dislocation density of each of single crystal substrates 11 to 19 is lower than the dislocation density of support portion 30, crystal quality of silicon carbide substrate can be made particularly higher in each of single crystal substrates 11 to 19. Further, since stress in silicon carbide substrate is alleviated by voids V1 and Vc, warpage of silicon carbide substrate 81 can be reduced.

Further, the number of voids per unit volume is larger in support portion 30 than in each of single crystal substrates 11 to 19. Therefore, it is possible to surely provide sufficiently large number of voids to alleviate stress by increasing the number of voids in support portion 30 while holding down the number of voids in each of single crystal substrates 11 to 19. Thus, warpage of silicon carbide substrate 81 can be reduced without degrading the quality of single crystal substrates 11 to 19.

Further, since first and second front-side surfaces F1 and F2 (FIG. 2) are formed, the surface area of silicon carbide substrate 81 can be made larger than when only the first front-side surface F1 is formed.

Further, space GP has filled portion 20 partially filling space GP to connect the first and second front-side surfaces F1 and F2. Thus, deposition of foreign matter in space GP can be prevented.

Further, since the porosity of space GP (second porosity) is higher than the porosity of single crystal substrate 11 (first porosity), filled portion 20 is more susceptible to deformation. This means that stress can more easily be alleviated by filled portion 20 and, hence, warpage of silicon carbide substrate 81 can further be reduced. Preferably, the porosity of space GP is made larger than the porosity of each of other single crystal substrates 12 to 19.

Preferably, single crystal substrate 11 has a first concentration as impurity concentration per unit volume, and support portion 30 has a second concentration as the impurity concentration per unit volume. The second concentration is higher than the first concentration. Thus, electric resistance of support portion 30 can be made lower.

Preferably, the number of voids per unit volume in support portion 30 is at least 10 cm⁻³. Thus, warpage of silicon carbide substrate 81 can further be reduced.

Preferably, the number of voids mentioned above represents the number of voids having the volume of at least 1 μm³. Thus, warpage of silicon carbide substrate 81 can further be reduced.

Preferably, each of single crystal substrates 11 to 19 has the SiC crystal structure of 4H polytype. Hence, silicon carbide substrate 81 suitable for the manufacture of power semiconductor can be obtained.

Preferably, in order to prevent cracking of silicon carbide substrate 81, difference in coefficient of thermal expansion between support portion 30 and single crystal substrates 11 to 19 is made as small as possible in silicon carbide substrate 81. Thus, warpage of silicon carbide substrate 81 can further be reduced. For this purpose, support portion 30 may be adapted, for example, to have the same crystal structure as that of single crystal substrates 11 to 19.

Preferably, in-plane variation of thickness of support portion 30 and each of the group 10 of single crystal substrates (FIG. 4) prepared before heat treatment is made as small as possible. By way of example, the variation is limited to at most 10 μm.

Electric resistance of support portion 30 prepared before heat treatment is set preferably lower than 50 mΩ·cm and more preferably lower than 10 mΩ·cm.

The impurity concentration of support portion 30 of silicon carbide substrate 81 is preferably set to at least 5×10¹⁸ cm⁻³, and more preferably at least 1×10²⁰ cm⁻³. When a vertical semiconductor device in which current is caused to flow in the vertical direction such as a vertical MOSFET (Metal Oxide Field Effect Transistor) is manufactured using silicon carbide substrate 81 as such, on-resistance of the vertical semiconductor device can be reduced.

The average electric resistance of silicon carbide substrate 81 is preferably at most 5 mΩ·cm, and more preferably, at most 1 mΩ·cm.

Preferably, the thickness of silicon carbide substrate 81 (dimension in the vertical direction in FIG. 2) is at least 300 μm.

Preferably, the first front-side surface F1 has an off angle of at least 50° and at most 65° with respect to the {0001} plane. Consequently, channel mobility at the first front-side surface F1 can be improved than when the first front-side surface is the {0001} plane. More preferably, either the first or second condition below is satisfied.

Under the first condition, an angle formed by the off orientation of first front-side surface F1 and the <1-100> direction of single crystal substrate 11 is at most 5°. More preferably, the off angle of first front-side surface F1 with respect to the {03-38} plane in the <1-100> direction of single crystal substrate 11 is at least −3° and at most 5°.

Under the second condition, an angle formed by the off orientation of first front-side surface F1 and the <11-20> direction of single crystal substrate 11 is at most 5°.

Though the preferable orientation of first front-side surface F1 of single crystal substrate 11 has been described in the foregoing, the same applies to the surface orientation of each of the remaining single crystal substrates 12 to 19.

### Embodiment 2

Mainly referring to FIG. 8, different from Embodiment 1 (FIG. 2), a silicon carbide substrate 82 in accordance with the present embodiment does not have void V1b (FIG. 2). Silicon carbide substrate 82 can be obtained by forming filled portion 20 mainly through material movement indicated by the arrow Ma (FIG. 5), substantially without material movement indicated by the arrow Mb (FIG. 5).

Except for this point, the structure is substantially the same as that of Embodiment 1 described above. Therefore, the same or corresponding elements are denoted by the same reference characters and description thereof will not be repeated. The present embodiment also attains effects similar to those attained by Embodiment 1.

### Embodiment 3

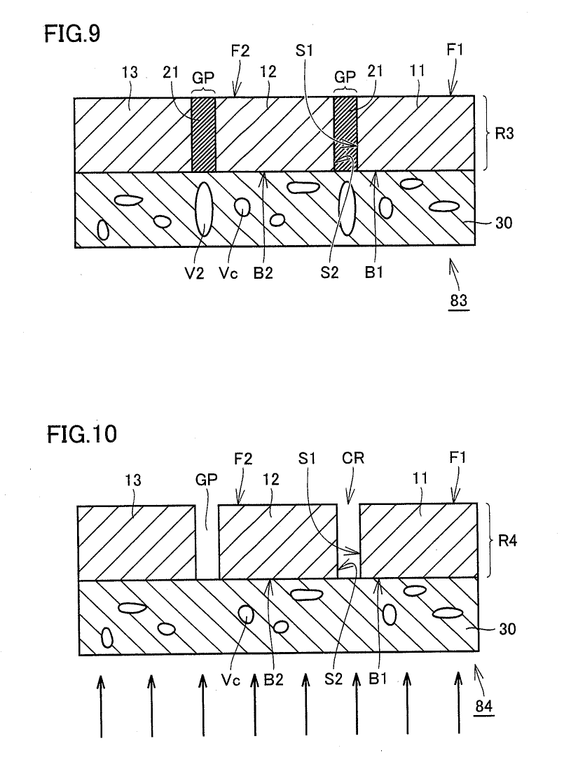

Mainly referring to FIG. 9, a silicon carbide substrate 83 in accordance with the present embodiment has a substrate region R3 in place of substrate region R1 (FIG. 2). Substrate region R3 has spaces GP fully filled with filled portions 21. Further, support portion 30 has voids V2 in addition to voids Vc. Voids V2 are positioned only in the inside of support portion 30. Silicon carbide substrate 83 can be obtained by continuing the heat treatment until voids V1 enter and are fully positioned in support portion 30.

The material of filled portion 21 may include, for example, silicon carbide (SiC), silicon (Si), adhesive, resist, resin or silicon oxide (SiO₂).

Except for this point, the structure is substantially the same as that of Embodiment 1 described above. Therefore, the same or corresponding elements are denoted by the same reference characters and description thereof will not be repeated. The present embodiment also attains effects similar to those attained by Embodiment 1.

### Embodiment 4

Referring to FIG. 10, a silicon carbide substrate 84 in accordance with the present embodiment has a substrate region R4 in place of substrate region R1 (FIG. 2). Substrate region R4 has unfilled space portions GP. In silicon carbide substrate 84, support portion 30 can be formed by depositing silicon carbide on the first and second backside surfaces B1 and B2, for example, as indicated by the central arrow in the figure. Voids Vc are formed at the time of this deposition. Support, portion 30 formed by the deposition may not necessarily have the single crystal structure, and it may have polycrystalline structure.

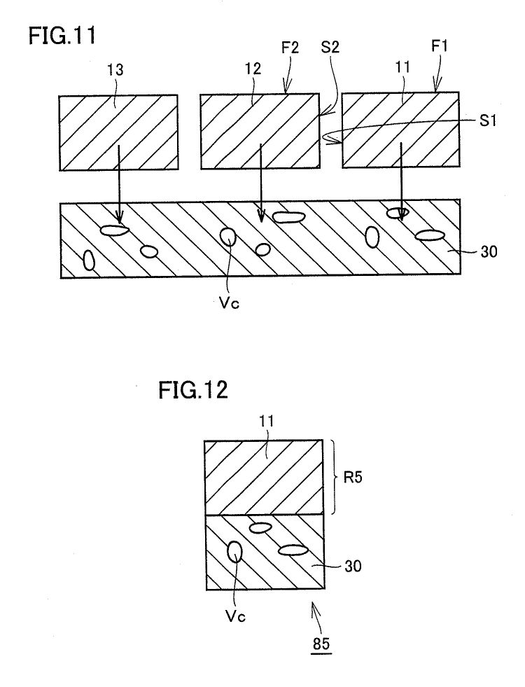

A modification of the present embodiment will be described with reference to FIG. 11. In the present embodiment, support portion 30 having voids Vc is prepared in advance. As support portion 30, one similar to that of Embodiment 1 or a polycrystalline body or a sintered body may be used. As indicated by the arrows in the figure, a surface of support portion 30 and backside surface of each of single crystal substrates 11 to 13 are joined. This joining may be done by heating the interface between each of single crystal substrates 11 to 13 and support portion 30.

Except for this point, the structure is substantially the same as that of Embodiment 1 described above. Therefore, the same or corresponding elements are denoted by the same reference characters and description thereof will not be repeated. The present embodiment also attains effects similar to those attained by Embodiment 1.

### Embodiment 5

Referring to FIG. 12, a silicon carbide substrate 85 in accordance with the present embodiment has a substrate region R5 in place of substrate region R1 (FIG. 2). Substrate region R5 has only the single crystal substrate 11, rather than single crystal substrates 11 to 19 (FIG. 1).

Except for this point, the structure is substantially the same as that of Embodiment 1 described above. Therefore, the same or corresponding elements are denoted by the same reference characters and description thereof will not be repeated. The present embodiment also attains effects similar to those attained by Embodiment 1.

### Embodiment 6

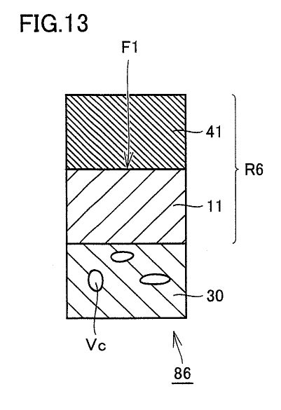

Referring to FIG. 13, a silicon carbide substrate 86 in accordance with the present embodiment has a substrate region R6 in place of substrate region R5 (FIG. 12). Substrate region R6 has a single crystal substrate 41 (third single crystal substrate) in addition to single crystal substrate 11. The third single crystal substrate 41 is joined to the first front-side surface F1 of single crystal substrate 11 (first single crystal substrate). Thus, substrate region R6 has a stacked structure.

### Seventh Embodiment

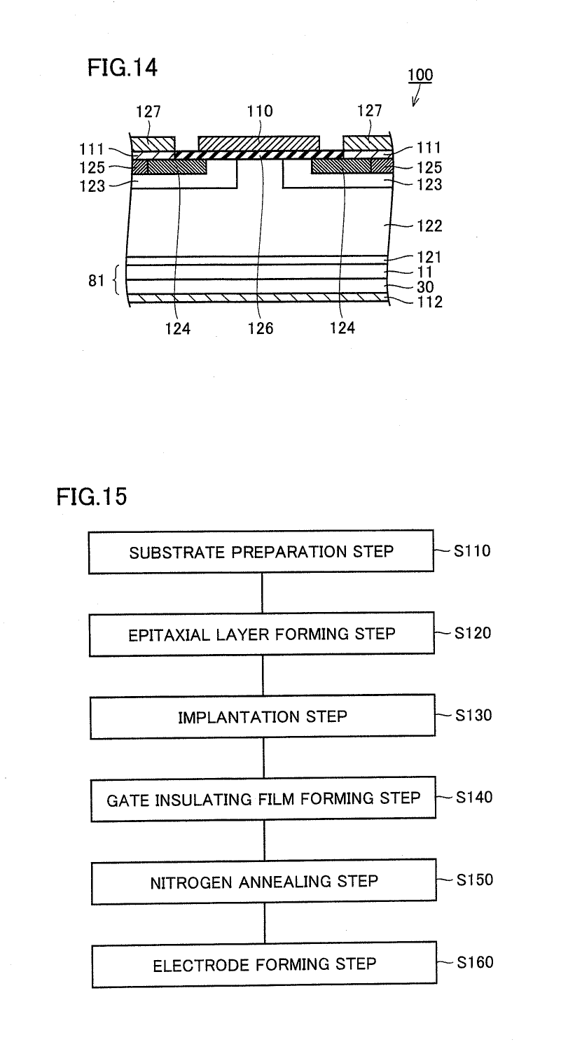

Referring to FIG. 14, a semiconductor device 100 in accordance with the present embodiment is a vertical DiMOSFET (Double Implanted Metal Oxide Semiconductor Field Effect Transistor), having silicon carbide substrate 81, a buffer layer 121, a breakdown voltage holding layer 122, a p-region 123, an n⁺ region 124, a p⁺ region 125, an oxide film 126, a source electrode 111, an upper source electrode 127, a gate electrode 110 and a drain electrode 112.

In the present embodiment, silicon carbide substrate 81 has n-type conductivity and, as described in Embodiment 1, it has support portion 30 and single crystal substrate 11. Drain electrode 112 is provided on support portion 30 such that support portion 30 is positioned between the drain electrode and single crystal substrate 11. Buffer layer 121 is provided on single crystal substrate 11 such that single crystal substrate 11 is positioned between the buffer layer and support portion 30.

Buffer layer 121 has n-type conductivity, and its thickness is, for example, 0.5 μm. The concentration of n-type conductive impurity in buffer layer 121 is, for example, 5×10¹⁷ cm⁻³.

Breakdown voltage holding layer 122 is formed on buffer layer 121, and it is formed of silicon carbide having n-type conductivity. The thickness of breakdown voltage holding layer 122 is 10 μm, and the concentration of n-type conductive impurity is 5×10¹⁵ cm⁻³.

On a surface of breakdown voltage holding layer 122, a plurality of p-regions 123 having p-type conductivity are formed spaced apart from each other. In p-region 123, an n⁺ region 124 is formed at a surface layer of p-region 123. A p⁺ region 125 is formed at a position next to n⁺ region 124. Extending from above n⁺ region 124 on one p-region 123 over breakdown voltage holding layer 122 exposed between two p-regions 123, the other p-region 123 and above n⁺ region 124 in the said the other p-region 123, oxide film 126 is formed. On oxide film 126, gate electrode 110 is formed. Further, on n⁺ region 124 and p⁺ region 125, source electrode 111 is formed. On source electrode 111, an upper source electrode 127 is formed.

In a region within 10 nm from the interface between oxide film 126 and each of the semiconductor layers, that is, n⁺ region 124, p⁺ region 125, p-region 123, and breakdown voltage holding layer 122, the highest concentration of nitrogen atoms is at least 1×10²¹ cm⁻³. Therefore, mobility particularly at the channel region below oxide film 126 (the portion of p-region 123 in contact with oxide film 126 between n⁺ region 124 and breakdown voltage holding layer 122) can be improved.

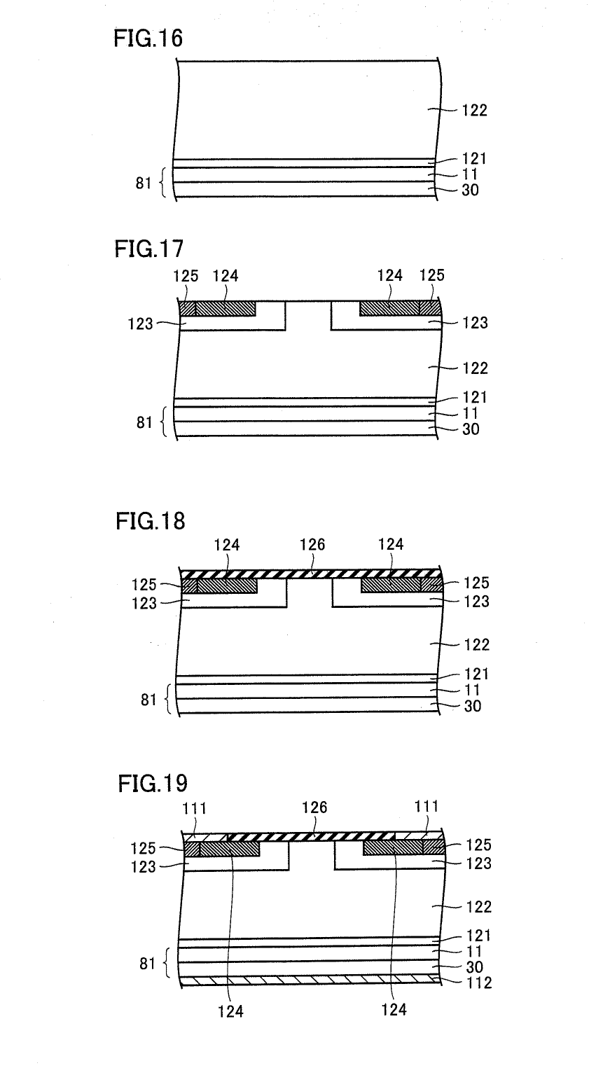

Next, the method of manufacturing semiconductor device 100 will be described. Though process steps only in the vicinity of single crystal substrate 11 among single crystal substrates 11 to 19 (FIG. 1) are shown in FIGS. 16 to 19, similar process steps are performed in the vicinity of each of single crystal substrates 12 to 19.

First, at the substrate preparation step (step S110: FIG. 15), silicon carbide substrate 81 (FIGS. 1 and 2) is prepared. Silicon carbide substrate 81 has n-type conductivity.

Referring to FIG. 16, at the epitaxial layer forming step (step S120: FIG. 15), buffer layer 121 and breakdown voltage holding layer 122 are formed in the following manner.

First, on a surface of single crystal substrate 11 of silicon carbide substrate 81, buffer layer 121 is formed. Buffer layer 121 is formed on silicon carbide having n-type conductivity and, by way of example, it is an epitaxial layer of 0.5 μm in thickness. Further, concentration of conductive impurity in buffer layer 121 is, for example, 5×10¹⁷ cm⁻³.

Next, breakdown voltage holding layer 122 is formed on buffer layer 121. Specifically, a layer formed of silicon carbide having n-type conductivity is formed by epitaxial growth. The thickness of breakdown voltage holding layer 122 is, for example, 10 μm. Concentration of n-type conductive impurity in breakdown voltage holding layer 122 is, for example, 5×10¹⁵ cm⁻³.

Referring to FIG. 17, at the implantation step (step S130: FIG. 15), p-region 123, n⁺ region 124 and n⁺ region 125 are formed in the following manner.

First, p-type impurity is selectively introduced to a part of breakdown voltage holding layer 122, so that p-region 123 is formed. Next, n-type conductive impurity is selectively introduced to a prescribed region to form n⁺ region 124, and p-type conductive impurity is selectively introduced to a prescribed region to form p⁺ region 125. Selective introduction of impurities is done using a mask formed, for example, of an oxide film.

Following the implantation step as such, an activation annealing treatment is done. By way of example, annealing is done in an argon atmosphere, at a heating temperature of 1700° C. for 30 minutes.

Referring to FIG. 18, the gate insulating film forming step (step S140: FIG. 15) is performed. Specifically, oxide film 126 is formed to cover breakdown voltage holding layer 122, p-region 123, n⁺ region 124 and p⁺ region 125. The film may be formed by dry oxidation (thermal oxidation). Conditions for dry oxidation are, for example, heating temperature of 1200° C. and heating time of 30 minutes.

Thereafter, the nitrogen annealing step (step S150) is done. Specifically, annealing is done in a nitrogen monoxide (NO) atmosphere. Conditions for this process are, for example, heating temperature of 1100° C. and heating time of 120 minutes. As a result, nitrogen atoms are introduced to the vicinity of interface between each of breakdown voltage holding layer 122, p-region 123, n⁺ region 124 and p⁺ region 125 and oxide film 126.

Following the annealing step using nitrogen monoxide, annealing using argon (Ar) gas as an inert gas may be performed. Conditions for the process are, for example, heating temperature of 1100° C. and heating time of 60 minutes.

Referring to FIG. 19, by the electrode forming step (step S160: FIG. 15), source electrode 111 and drain electrode 112 are formed in the following manner.

First, on oxide film 126, using photolithography, a resist film having a pattern is formed. Using the resist film as a mask, portions of oxide film 126 positioned on n⁺ region 124 and p⁺ region 125 are removed by etching. Thus, openings are formed in oxide film 126. Next, a conductive film is formed to be in contact with each of n⁺ region 124 and p′ region 125 in the openings. Then, the resist film is removed, whereby portions of the conductive film that have been positioned on the resist film are removed (lift off). The conductive film may be a metal film and, by way of example, it is formed of nickel (Ni). As a result of this lift off, source electrode 111 is formed.

Here, heat treatment for alloying is preferably carried out. By way of example, heat treatment is done in an atmosphere of argon (Ar) gas as an inert gas, at a heating temperature of 950° C. for 2 minutes.

Again referring to FIG. 14, on source electrode 111, upper source electrode 127 is formed. Further, on the backside surface of silicon carbide substrate 81, drain electrode 112 is formed. On oxide film 126, gate electrode 110 is formed. By the above-described steps, semiconductor device 100 is obtained.

It is noted that a structure having conductivity types reversed from the present embodiment, that is, p-type and n-type reversed, may be used.

Further, the silicon carbide substrate for fabricating semiconductor device 100 is not limited to silicon carbide substrate 81 in accordance with Embodiment 1, and it may be any of silicon carbide substrates 82 to 86 (Embodiments 2 to 6).

Further, though a vertical DiMOSFET has been described as an example, other semiconductor devices may be manufactured using the semiconductor substrate in accordance with the present invention. For instance, a RESURF-JFET (Reduced Surface Field-Junction Field Effect Transistor) or a Schottky diode may be manufactured.

### EXAMPLES

As support portion 30 (FIG. 3), a silicon carbide wafer having the diameter of 100 mm, thickness of 300 μm, polytype 4H, plane orientation of (03-38), n-type impurity concentration of 1×10²⁰ cm⁻³, micropipe density of 1×10⁴ cm⁻² and stacking fault density of 1×10¹⁵ cm⁻¹ was prepared. As each of the group 10 of single crystal substrates, that is, each of single crystal substrates 11 to 19 (FIG. 1), a silicon carbide wafer having the square shape of 20×20 mm, thickness of 300 μm, polytype 4H, plane orientation of (03-38), n-type impurity concentration of 1×10¹⁹ cm⁻³, micropipe density of 0.2 cm⁻² and stacking fault density smaller than 1 cm⁻¹ was prepared. Further, as each of the first and second heating bodies 91 and 92, a graphite piece was prepared.

Single crystal substrates 11 to 19 were arranged in a matrix on the first heating body 91. On the group 10 of single crystal substrates, support portion 30 was placed. Then, the second heating body 92 was placed on support portion 30. In this manner, a stacked body consisting of first heating body 91, group 10 of single crystal substrates, support portion 30 and second heating body 92 was prepared.

The stacked body described above was housed in heat-insulating container 40 (FIG. 3) of the heating apparatus. Next, the atmosphere in heat-insulating container 40 was set to nitrogen atmosphere of 1 Pa pressure. Thereafter, the temperature in heat-insulating container 40 was heated to about 2100° C. by heater 50. Here, heating was done by heater 50 positioned closer to the second heating body 92 than the first heating body 91. As a result, the temperature of second heating body 92 was made higher than the first heating body 91. Accordingly, the temperature of the group 10 of single crystal substrates facing the first heating body 91 was made lower than the temperature of support portion 30 facing the second heating body 92. This state was kept for 24 hours, to attain heat treatment. As a result, silicon carbide substrate 81 (FIGS. 1, 2) was obtained.

The number of voids per unit volume of support portion 30 of silicon carbide substrate 81 was 10 cm⁻³ or higher. Further, impurity concentration in support portion 30 was 5×10²⁰ cm⁻³. Specifically, the impurity concentration of support portion 30 after heat treatment was made higher than the value 1×10²⁰ cm⁻³ before heat treatment. The reason for this is considered that support portion 30 took in nitrogen in the atmosphere described above.

A cross-section of silicon carbide substrate 81 was inspected by an SEM (Scanning Electron Microscope), and it was found that gaps GQ (FIG. 5) that had existed at the interface between single crystal substrate 11 and support portion 30 before heat treatment were substantially eliminated.

In the present example, the temperature of single crystal substrate 11 was made lower than the temperature of support portion 30 in the heat treatment, while an experiment of heat treatment without such temperature difference was conducted. As a result, it was found that more gaps GQ were left as compared with the example of the invention.

As further samples of the inventive example, silicon carbide substrates having the diameters of 50 mm, 75 mm, 100 mm, 125 mm and 150 mm were fabricated for each of plane orientations (0001) and (03-38), by the same method as described above. As comparative examples, substrates formed of single crystal corresponding to the dimensions mentioned above were prepared. Each of these substrates was subjected to ion implantation and activation annealing. Conditions for activation annealing were: atmosphere was Ar atmosphere; pressure was 90 kPa; heat increase rate was 100° C./min; temperature was 1800° C.; and holding time was 30 minutes.

Warpage of each of the substrates obtained in the above-described manner was measured. The results were as shown in Table 1.

TABLE 1

| | | Warpage (μm) | | | | |
|---|---|---|---|---|---|---|
| | | 50 mm | 75 mm | 100 mm | 125 mm | 150 mm |
| Comparative | (0001) | <40 | <50 | <100 | <200 | <500 |
| Examples | (03-38) | <30 | <50 | <70 | <140 | <300 |
| Inventive | (0001) | <20 | <30 | <40 | <50 | <70 |
| Examples | (03-38) | <20 | <20 | <30 | <40 | <50 |

The results indicated that warpage of substrates could be reduced in the samples of the invention.

Further, probability of cracking of each of the substrates was measured. The results were as shown in Table 2.

TABLE 2

| | | Probability of Cracking | | | | |
|---|---|---|---|---|---|---|
| | | 50 mm | 75 mm | 100 mm | 125 mm | 150 mm |
| Comparative | (0001) | 1/10 | 1/10 | 3/10 | 4/10 | 7/10 |
| Examples | (03-38) | 0/10 | 2/10 | 2/10 | 4/10 | 6/10 |
| Inventive | (0001) | 0/10 | 0/10 | 0/10 | 0/10 | 0/10 |
| Examples | (03-38) | 0/10 | 0/10 | 0/10 | 0/10 | 0/10 |

The results indicated that probability of cracking could be reduced in the samples of the invention.

Though Ar atmosphere was used for activation annealing in the examples above, similar results were observed when other inert gas atmosphere such as He or N₂ gas atmosphere was used.

Correlation between the number of voids per unit volume in support portion 30 of silicon carbide substrate 81 and the warpage of substrate was studied. It was found that the smaller the number of voids per unit volume, the larger became the warpage of substrate. Further, it was found that crack was sometimes observed when the number of voids having the volume of 1 μm³ or larger per unit volume was smaller than 10 cm⁻³.

The embodiments as have been described here are mere examples and should not be interpreted as restrictive. The scope of the present invention is determined by each of the claims with appropriate consideration of the written description of the embodiments and embraces modifications within the meaning of, and equivalent to, the languages in the claims.

### DESCRIPTION OF THE REFERENCE SIGNS

11 single crystal substrate (first single crystal substrate), 12 single crystal substrate (second single crystal substrate), 13-19 single crystal substrates, 20 filled portion, 30 support portion, 41 single crystal substrate (third single crystal substrate), 81-86 silicon carbide substrates, 91 first heating body, 92 second heating body, 100 semiconductor device, R1, R3-R6 substrate regions.

1. A silicon carbide substrate, comprising:
a substrate region including a first single crystal substrate, said first single crystal substrate having a first front-side surface and a first backside surface opposite to each other and a first side surface connecting said first front-side surface and said first backside surface; and
a support portion joined to said first backside surface; wherein
dislocation density of said first single crystal substrate is lower than the dislocation density of said support portion, and at least one of said substrate region and said support portion has voids.

2. The silicon carbide substrate according to claim 1, wherein
number of voids per unit volume in said support portion is larger than in said first single crystal substrate.

3. The silicon carbide substrate according to claim 1, wherein
said first single crystal substrate has a first concentration as impurity concentration per unit volume, said support portion has a second concentration as impurity concentration per unit volume, and said second concentration is higher than said first concentration.

4. The silicon carbide substrate according to claim 1, wherein
said substrate region includes a second single crystal substrate, said second single crystal substrate has a second front-side surface and a second backside surface opposite to each other and a second side surface connecting said second front-side surface and said second backside surface, and said second backside surface is joined to said support portion.

5. The silicon carbide substrate according to claim 4, wherein
said substrate region includes a space portion positioned between said first and second side surfaces facing each other, and said space portion has a filled portion partially filling said space portion.

6. The silicon carbide substrate according to claim 5, wherein
said first single crystal substrate has a first porosity, said space portion has a second porosity, and said second porosity is higher than said first porosity.

7. The silicon carbide substrate according to claim 1, wherein
said substrate region includes a third single crystal substrate joined to said first front-side surface of said first single crystal substrate.

8. The silicon carbide substrate according to claim 1, wherein number of voids per unit volume in said support potion is at least 10 cm⁻³.

9. The silicon carbide substrate according to claim 8, wherein
said number of voids relates to voids whose volume is at least 1 μm³.

10. The silicon carbide substrate according to claim 1, wherein
said first front-side surface has an off angle of at least 50° and at most 65° with respect to the {0001} plane.

11. The silicon carbide substrate according to claim 10, wherein
an angle formed by off orientation of said first front-side surface and <1-100> direction of said first single crystal substrate is at most 5°.

12. The silicon carbide substrate according to claim 11, wherein
off angle of said first front-side surface with respect to the {03-38} plane in <1-100> direction of said first single crystal substrate is at least −3° and at most 5°.

13. The silicon carbide substrate according to claim 10, wherein
an angle formed by off orientation of said first front-side surface and <11-20> direction of said first single crystal substrate is at most 5°.

14. The silicon carbide substrate according to claim 1, wherein
said first backside surface of said first single crystal substrate is formed by slicing.
